(19) United States
(12) Patent Application Publication
(10) Pub. No.: US 2008/0258303 A1
(43) Pub. Date: Oct. 23, 2008

(54) Novel structure for reducing low-k dielectric damage and improving copper EM performance

(76) Inventors: Ming-Shih Yeh, Chupei City (TW); Tien-I Bao, Hsin-Chu (TW); David Ding-Chung Lu, Hsin-Chu City (TW)

Correspondence Address: SLATER & MATSIL, L.L.P., 17950 PRESTON ROAD, SUITE 1000, DALLAS, TX, 75252, US

(21) Appl. No.: 11/788,986

(22) Filed: Apr. 23, 2007

(51) Int. Cl. H01L 23/528; H01L 21/44

(52) U.S. Cl. 257/751; 438/622; 257/E23.152; 257/E21.476

(57) ABSTRACT

A semiconductor structure and methods for forming the same are provided. The semiconductor structure includes a dielectric layer; a chemical mechanical polish (CMP) stop layer on the dielectric layer; a conductive wiring in the dielectric layer; and a metal cap over the conductive wiring.

### TECHNICAL FIELD

This invention is related generally to integrated circuits, and more particularly to the structure and formation methods of interconnect structures.

### BACKGROUND

A commonly used method for forming metal lines and vias is known as “damascene.” Generally, this method involves forming an opening in a dielectric layer, which separates the vertically spaced metallization layers. The opening is typically formed using conventional lithographic and etching techniques. After the formation, the opening is filled with copper or copper alloys to form a via or a trench. Excess metal material on the surface of the dielectric layer is then removed by chemical mechanical polish (CMP). The remaining copper or copper alloy forms vias and/or metal lines.

Copper has replaced aluminum because of its lower resistivity. However, copper still suffers from electro migration (EM) and stress migration (SM) reliability issues as geometries continue to shrink and current densities increase.

FIG. 1 illustrates a cross-sectional view of a conventional interconnect structure. Typically, in the formation process of the structure shown in FIG. 1, an opening is formed in low-k dielectric 2. Diffusion barrier layer 6 is then formed in the opening, followed by filling the opening with copper. A chemical mechanical polish (CMP) is then performed to remove excess copper, forming copper line 4 in the opening. Metal cap 8 is then formed on copper line 4. Diffusion barrier layer 6 and metal cap 8 having the function of sealing copper line 4, and hence preventing copper from diffusing into low-k dielectric layer 2 and overlying/underlying low-k dielectric layers. Etch stop layer (ESL) 10 may then be formed on the top surface of copper line 4 and metal cap 8.

The conventional interconnect structure suffers drawbacks. In the CMP process for forming copper line 4, low-k dielectric layer 2 is exposed to slurries, and thus may be damaged. In addition, metal cap 8 is typically formed using electroless plating, which involves submerging the wafer into a plating solution. However, the wetability of low-k dielectric layer 2 is typically low, and thus the resulting metal cap 8 will have a non-uniform thickness. Particularly, at locations near the interface between copper line 4 and diffusion barrier layer 6, incomplete contact between the plating solution and low-k dielectric layer 2 may occur. As a result, metal cap 8 may not be able to completely cover copper line 4. New interconnect structures and formation methods are thus needed to solve the above-discussed problems.

### SUMMARY OF THE INVENTION

In accordance with one aspect of the present invention, a semiconductor structure includes a dielectric layer; a chemical mechanical polish (CMP) stop layer on the dielectric layer; a conductive wiring in the dielectric layer; and a metal cap over the conductive wiring.

In accordance with another aspect of the present invention, a semiconductor structure includes a substrate; a low-k dielectric layer over the substrate; an additional dielectric layer on the low-k dielectric layer, wherein the additional dielectric layer has a higher dielectric constant than the low-k dielectric layer; an opening extending from a top surface of the additional dielectric layer into the low-k dielectric layer; a diffusion barrier layer lining the opening; a copper line in the opening and over the diffusion barrier layer; and a metal cap on the copper line.

In accordance with yet another aspect of the present invention, a method for forming a semiconductor structure includes forming a dielectric layer; forming a chemical mechanical polish (CMP) stop layer on the dielectric layer; forming a conductive wiring in the dielectric layer; and forming a metal cap over the conductive wiring.

In accordance with yet another aspect of the present invention, a method for forming a semiconductor structure includes providing a semiconductor substrate; forming a low-k dielectric layer over the semiconductor substrate; forming an additional dielectric layer on the low-k dielectric layer; forming an opening extending from a top surface of the additional dielectric layer into the low-k dielectric layer; filling copper into the opening; performing a chemical mechanical polish (CMP) to remove excess copper, wherein remaining copper in the opening forms a copper line, and wherein a top surface of the copper line is substantially level with a top surface of the additional dielectric layer; and selectively forming a metal cap layer on the copper line.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a conventional interconnect structure including a metal cap and an etch stop layer;

FIGS. 2 through 6 are cross-sectional views of intermediate stages in the manufacturing of an embodiment of the present invention, wherein a single damascene structure is formed; and

FIG. 7 illustrates an embodiment of the present invention, wherein a dual damascene structure is formed.

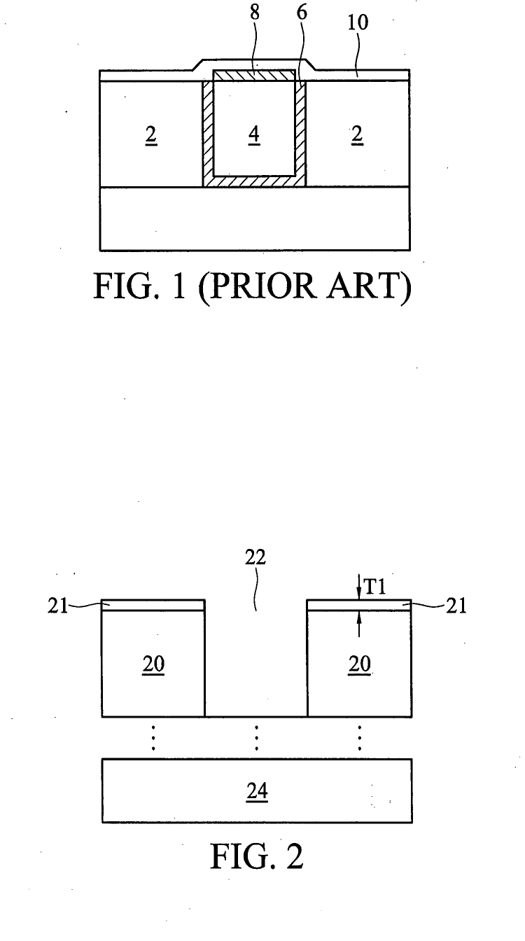

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

FIG. 2 illustrates a starting structure, with low-k dielectric layer 20 formed over semiconductor substrate 24. Semiconductor substrate 24 may include commonly used semiconductor materials such as silicon, SiGe, and the like, and has integrated circuits (not shown) formed thereon. In the preferred embodiment, low-k dielectric layer 20 is an inter-metal dielectric (IMD) layer, preferably having a dielectric constant (k value) lower than about 3.5. Furthermore, the k value of low-k dielectric layer 20 may be lower than about 2.5 (hence is referred to as an extra low-k dielectric layer). Low-k dielectric layer 20 preferably contains nitrogen, carbon, hydrogen, oxygen, fluorine, and combinations thereof. In an embodiment, low-k dielectric layer 20 may have carbon and hydrogen containing terminals, such as CH₃ terminals. Low-k dielectric layer 20 tends to be hydrophobic, and thus has difficulty in achieving a uniform contact with the plating solution used in the subsequent plating process.

Dielectric layer 21, which acts as a chemical mechanical polish (CMP) stop layer, is formed on dielectric layer 20. Preferably, CMP stop layer 21 includes a material selected from silicon oxide, silicon carbide, silicon oxycarbide, silicon nitride, silicon oxynitride, and combinations thereof. The k value of dielectric layer 21 may be between about 2.2 and about 5.0, and is preferably greater than the k value of low-k dielectric layer 20. The preferred formation method is plasma enhanced chemical vapor deposition (PECVD). However, other commonly used methods such as high-density plasma CVD (HDPCVD), atomic layer CVD (ALCVD), and the like can also be used. In an exemplary embodiment, CMP stop layer 21 includes silicon nitride, and is formed in a chamber in which gaseous precursors such as silane (SiH₄) and ammonia (NH₃) are introduced for a chemical reaction. Preferably, CMP stop layer 21 has a thickness of between about 50 Å and about 300 Å, and more preferably about 300 Å. One skilled in the art will realize, however, that the dimensions recited throughout the description are merely examples, and will scale with the scaling of integrated circuits. Trench 22 is formed in low-k dielectric layer 20 and CMP stop layer 21.

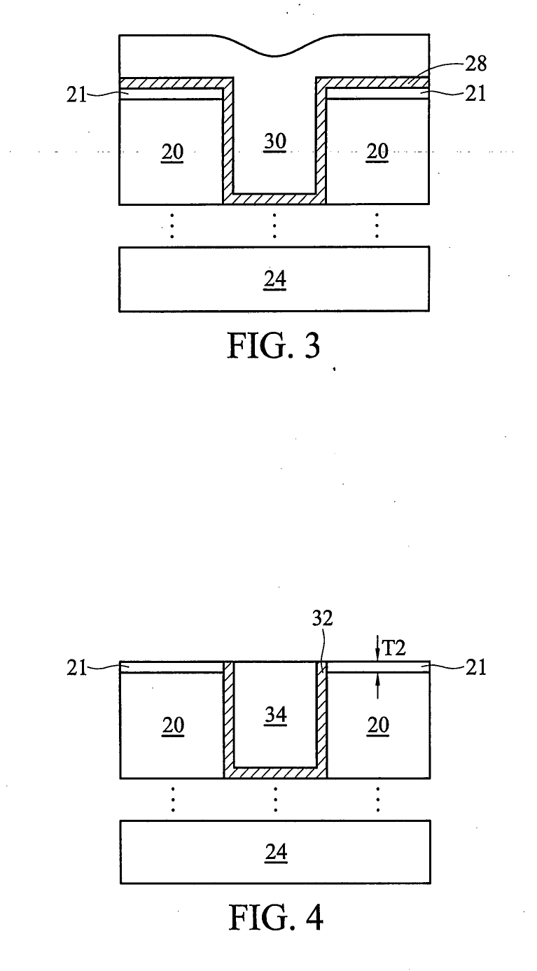

Referring to FIG. 3, a blanket diffusion barrier layer 28 is formed to cover the sidewalls and the bottom of trench 22. Diffusion barrier layer 28 is preferably formed of a material selected from titanium, titanium nitride, tantalum, tantalum nitride, ruthenium, ruthenium nitride, and combinations thereof. The preferred formation methods include physical vapor deposition (PVD), atomic layer deposition (ALD), and other commonly used methods.

A seed layer (not shown), which preferably includes copper or copper alloys, is formed on diffusion barrier layer 28. In an exemplary embodiment, the seed layer is formed using electroless plating or physical vapor deposition (PVD). Conductive material 30 is then filled into trench 22, for example, by electro plating. Conductive material 30 preferably includes copper or copper alloys, although other materials such as aluminum, silver, refractory metals including tungsten, tantalum, tantalum nitride, titanium, titanium nitride, and combinations thereof, can also be used.

Referring to FIG. 4, a CMP is performed to remove excess filling materials, so that the top surface of the conductive material 30 is substantially level with a top surface of CMP stop layer 21. Diffusion barrier layer 32 and conductive line 34 are thus formed. Throughout the description, conductive line 34 is alternatively referred to as copper line 34, although it may include other conductive materials.

Preferably, over-polishing is performed to achieve a uniform pattern across the entire wafer. Accordingly, after the CMP process, the thickness of CMP stop layer 21 may be reduced. In an exemplary embodiment, the remaining CMP stop layer 21 has a thickness of about 100 Å.

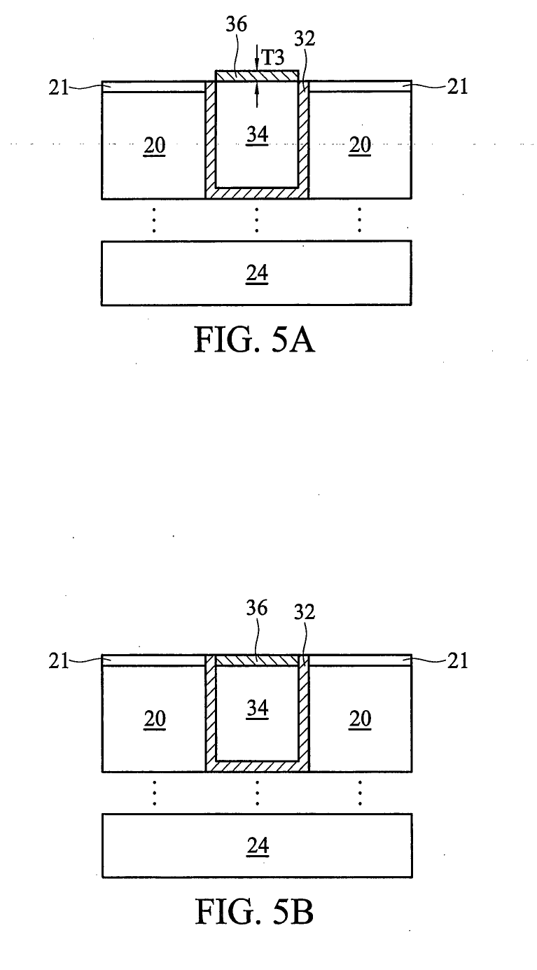

FIG. 5A illustrates the selective formation of metal cap 36 on conductive line 34. Metal cap 36 preferably comprises materials such as cobalt, nickel, tungsten, molybdenum, silicon, zinc, chrome, boron, phosphorus, nitrogen, and combinations thereof. The preferred thickness of metal cap 36 is between about 10 Å and about 500 Å, and more preferably between about 50 Å and about 100 Å, although different thicknesses may be used.

In the preferred embodiment, metal cap 36 is formed by electroless-plating in a plating solution, and is selectively formed only on copper line 34, but not on low-k dielectric layer 20. This may be achieved by using a palladium catalyst. An advantageous feature of the present invention is that CMP stop layer 21 is more hydrophilic than low-k dielectric layer 20. Therefore, the contact between the plating solution and CMP stop layer 21 is more uniform than the contact between the plating solution and low-k dielectric layer 20. This in turn improves the contact between the plating solution and copper line 34. A better uniformity in the thickness of metal cap 36 is thus achieved.

Typically, after the CMP process, but before the formation of metal cap 36, the top surface of copper line 34 tends to have a native copper oxide layer due to the exposure of copper line 34 in an oxygen-containing environment. In the pre-cleaning process, the copper oxide layer is removed using an acid, and hence a recess is formed. Metal cap 36 is thus formed in the recess, as shown in FIG. 5B. In the preferred embodiment, the top surface of metal cap layer 36 substantially levels with the top surface of CMP stop layer 21. The depth of the recess, however, may be greater than or less than the desirable thickness of metal cap 36. Correspondingly, the top surface of metal cap 36 may be higher than or lower than the top surface of CMP stop layer 21.

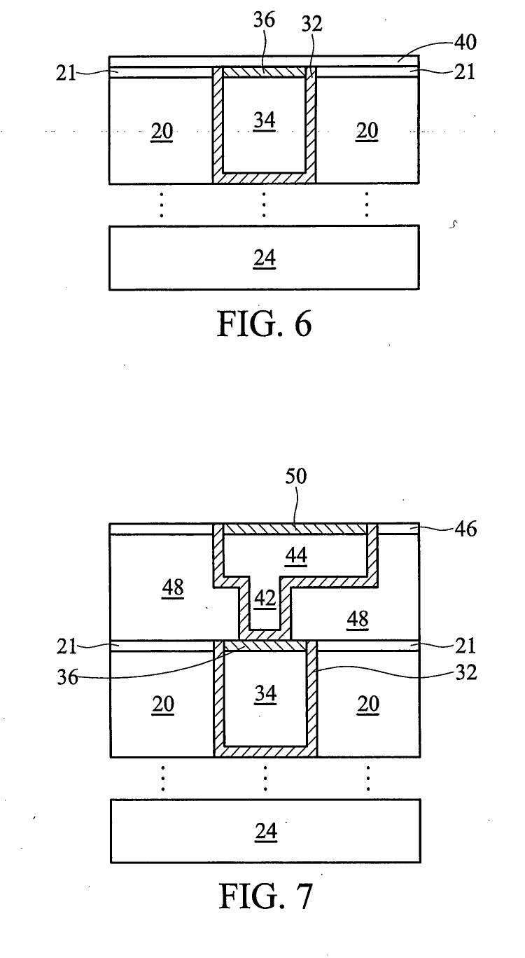

FIG. 6 illustrates the formation of an optional etch stop layer (ESL) 40. ESL 40 preferably has a dielectric constant of less than about 4.0, and may include carbon and/or nitrogen based materials such as silicon carbide, silicon nitride, silicon oxycarbide, silicon oxynitride, and combinations thereof.

In the embodiment discussed in the preceding paragraphs, a single damascene structure is formed. One skilled in the art will realize that the teaching is readily available for forming dual damascene processes. FIG. 7 illustrates a dual damascene embodiment, which includes via 42 and the overlying copper line 44 formed in low-k dielectric layer 48. Using essentially the same process steps as discussed in the preceding paragraphs, CMP stop layer 46 and metal cap 50 may be formed.

The embodiments of the present invention have the advantageous feature of improving the wetability in the plating of metal caps, hence the uniformity of the metal caps. In addition, the CMP stop layers protect low-k dielectric layers from the damage caused by the CMP processes. Furthermore, with the CMP stop layers, the uniformity of the CMP processes is improved, accordingly, the metal features in a wafer have more uniform thicknesses, and the uniformity in sheet resistances of the metal lines is improved.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor structure comprising:
a dielectric layer;
a chemical mechanical polish (CMP) stop layer on the dielectric layer;
a conductive wiring in the dielectric layer; and
a metal cap over the conductive wiring.

2. The semiconductor structure of claim 1 further comprising a diffusion barrier layer between the conductive wiring and the dielectric layer, wherein the diffusion barrier layer has a top edge substantially leveled with a top surface of the CMP stop layer.

3. The semiconductor structure of claim 2, wherein the metal cap and the conductive wiring have an interface lower than the top edge of the diffusion barrier layer.

4. The semiconductor structure of claim 3, wherein a top surface of the metal cap substantially levels with the top surface of the CMP stop layer.

5. The semiconductor structure of claim 1, wherein the CMP stop layer comprises a material selected from the group consisting essentially of silicon oxide, silicon carbide, silicon oxycarbide, silicon nitride, silicon oxynitride, and combinations thereof.

6. The semiconductor structure of claim 5, wherein the CMP stop layer has a dielectric constant of between about 2.2 and about 5.0.

7. The semiconductor structure of claim 1, wherein the metal cap has a thickness of between about 50 Å and about 100 Å.

8. The semiconductor structure of claim 1, wherein the CMP stop layer has a thickness of between 50 A and 300 A.

9. The semiconductor structure of claim 1, wherein the dielectric layer has a dielectric constant of lower than a dielectric constant of the CMP stop layer.

10. A semiconductor structure comprising:
a substrate;
a low-k dielectric layer over the substrate;
an additional dielectric layer on the low-k dielectric layer, wherein the additional dielectric layer has a higher dielectric constant than the low-k dielectric layer;
an opening extending from a top surface of the additional dielectric layer into the low-k dielectric layer;
a diffusion barrier layer lining the opening;
a copper line in the opening and over the diffusion barrier layer; and
a metal cap on the copper line.

11. The semiconductor structure of claim 10, wherein the diffusion barrier layer has a top edge substantially leveled with a top surface of the CMP stop layer.

12. The semiconductor structure of claim 11, wherein the metal cap and the copper line have an interface lower than the top edge of the diffusion barrier layer.

13. The semiconductor structure of claim 12, wherein a top surface of the metal cap substantially levels with a top surface of the additional dielectric layer.

14. The semiconductor structure of claim 10, wherein the additional dielectric layer comprises a material selected from the group consisting essentially of silicon oxide, silicon carbide, silicon oxycarbide, silicon nitride, silicon oxynitride, and combinations thereof.

15. The semiconductor structure of claim 10, wherein the CMP stop layer has a dielectric constant of between about 2.2 and about 5.0.

16. The semiconductor structure of claim 10, wherein the metal cap has a thickness of between about 50 Å and about 100 Å.

17. The semiconductor structure of claim 10, wherein the CMP stop layer has a thickness of between 50 Å and 300 Å.

18. The semiconductor structure of claim 10, wherein the low-k dielectric layer has a dielectric constant of lower than a dielectric constant of the additional dielectric layer.

19. The semiconductor structure of claim 10 further comprising an etch stop layer on the metal cap and the additional dielectric layer.

20. A method for forming a semiconductor structure, the method comprising:
forming a dielectric layer;
forming a chemical mechanical polish (CMP) stop layer on the dielectric layer;
forming a conductive wiring in the dielectric layer; and
forming a metal cap over the conductive wiring.

21. The method of claim 20, wherein the step of forming the conductive wiring comprises:
forming an opening extending from a top surface of the CMP stop layer into the dielectric layer;
forming a diffusion barrier layer lining the opening;
filling the opening with a metallic material; and
performing a CMP to remove excess metallic material, wherein a portion of the metallic material in the opening forms the conductive wiring.

22. The method of claim 21, wherein the metal cap is selectively formed on the conductive wiring using electroless plating.

23. The method of claim 22 further comprising a pre-cleaning step before the step of forming the metal cap, wherein the pre-cleaning removes a top oxide layer of the conductive wiring.

24. The method of claim 20 further comprising forming an etch stop layer on the metal cap and the CMP stop layer.

25. A method for forming a semiconductor structure, the method comprising:
providing a semiconductor substrate;
forming a low-k dielectric layer over the semiconductor substrate;
forming an additional dielectric layer on the low-k dielectric layer;
forming an opening extending from a top surface of the additional dielectric layer into the low-k dielectric layer;
filling copper into the opening;
performing a chemical mechanical polish (CMP) to remove excess copper, wherein remaining copper in the opening forms a copper line, and wherein a top surface of the copper line substantially levels with a top surface of the additional dielectric layer; and
selectively forming a metal cap layer on the copper line.

26. The method of claim 25 further comprising forming a diffusion barrier layer before the step of filling copper, wherein after the step of CMP, a top edge of the diffusion barrier layer substantially levels with the top surface of the additional dielectric layer.

27. The method of claim 25, wherein the step of forming the metal cap comprises electroless plating.

28. The method of claim 25, wherein the step of performing the CMP comprises over-polishing the additional dielectric layer.

29. The method of claim 25 further comprising a pre-cleaning step before the step of forming the metal cap, wherein the pre-cleaning removes a top oxide layer of the copper line.

30. The method of claim 25 further comprising forming an etch stop layer on the metal cap and the additional dielectric layer.
